(19) United States
(12) Patent Application Publication
(10) Pub. No.: US 2012/0003912 A1
(43) Pub. Date: Jan. 5, 2012

(54) PROVISIONING OF COOLING RESOURCES THROUGH A DELIVERY APPARATUS

(76) Inventors: Christopher Edward HOOVER, Campbell, CA (US); Cullen E. BASH, Los Gatos, CA (US)

(21) Appl. No.: 12/828,596

(22) Filed: Jul. 1, 2010

(51) Int. Cl. H05K 5/02; F24F 11/02; F24F 13/10

(52) U.S. Cl. 454/184; 454/333; 454/256

(57) ABSTRACT

In a method for provisioning cooling resources to at least one device through at least one delivery apparatus, a recirculation value of cooling resources supplied to the at least one device from the at least one delivery apparatus and a cooling effectiveness (CE) value of the at least one delivery apparatus are computed. In addition, a determination as to whether provisioning of the cooling resources supplied to the at least one device through the at least one delivery apparatus is to be adjusted is made based upon the computed recirculation and CE values and an instruction to adjust one of a temperature of cooling resources supplied by at least one zonal actuator and an opening of the at least one delivery apparatus is outputted in response to a determination that provisioning of the cooling resource is to be adjusted.

### BACKGROUND

A data center may be defined as a location, for instance, a room, that houses computer systems arranged in a number of racks. Standard racks may be configured to house a number of computer systems, for instance, about forty (40) to eighty (80) systems. The computer systems typically include a number of components, such as, one or more of printed circuit boards (PCBs), mass storage devices, power supplies, processors, micro-controllers, semi-conductor devices, and the like, that may dissipate relatively significant amounts of heat during the operation of the respective components. For example, a typical computer system comprising multiple microprocessors may dissipate approximately 250 W of power. Thus, a rack containing forty (40) computer systems of this type dissipates approximately 10 KW of power.

Computer rooms are known to be built with raised floors. The under floor volume is pressurized with a cooling fluid, often chilled air. Where cooling is needed, the cooling fluid blows upwards through vented floor tiles. These vented floor tiles are often mechanically constructed devices, which contain fixed venting (covering a known percentage of their surface area) or are designed with adjustable louvers or sliding apertures to allow more or less of the cooling fluid to flow through the tile. The cooling fluid flows upwards through the vented floor tiles towards the hot computer systems and is circulated throughout the computer systems, causing a cooling effect.

The need for the cooling fluid varies in the short term as load gets passed around the room and in the long term as more computer systems are added to the room or racks are vacated. As such, some types of vented floor tiles are known to incorporate servo mechanisms to adjust louvers contained therein, under computer control, to the desired angle in order to vary the volume flow rate of the cooling fluid. These types of vented floor tiles are often controlled based upon data collected by sensing grids, which typically determine the required volume flow rate of the cooling fluid by monitoring the temperature of computer systems within the room.

In most data centers, the environment is dynamic in that the workload and power dissipation fluctuate considerably over both short-term and long-term time scales. As such, airflow requirements vary continuously. However, the airflow to the equipment is relatively constant, as computer room air conditioning units (CRAC units) and vent tiles are adjusted infrequently due to labor costs and lack of expertise. To compensate for this lack of adjustment, many data centers are grossly over provisioned with airflow. Alternatively, many data centers lack sufficient airflow delivery in certain local areas.

### BRIEF DESCRIPTION OF THE DRAWINGS

Embodiments are illustrated by way of example and not limited in the following figure(s), in which like numerals indicate like elements, in which:

FIG. 1A illustrates a perspective view of a delivery apparatus adjusting system, according to an embodiment of the invention;

FIG. 1B illustrates a perspective view of a sensing apparatus, according to an embodiment of the invention;

FIGS. 2-4, respectively, illustrate flow diagrams of methods for provisioning cooling resources to a device through a delivery apparatus, according to embodiments of the invention;

FIGS. 5A and 5B, collectively, illustrate a flow diagram of a method of provisioning cooling resources to a plurality of locations in an infrastructure through a plurality of delivery apparatuses, according to an embodiment of the invention; and

FIG. 6 illustrates a computer system, which may be employed to perform the methods depicted in FIGS. 2-5, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is a method for provisioning cooling resources to at least one device through at least one delivery apparatus. In the method, data is collected and processed to determine how the delivery apparatus and/or nearby zonal actuators, such as, air conditioning (AC) units, or other types of apparatuses configured to supply cooling resources, are to be adjusted to ensure that devices that receive cooling resources through the delivery apparatus are properly thermally managed. In addition, adjustments for the delivery apparatus and/or nearby zonal actuators are determined to substantially optimize efficiencies of the zonal actuators in supplying the devices with adequate cooling resources. Moreover, the method disclosed herein determines an optimized order in which the delivery apparatuses and/or zonal actuators are to be adjusted to one or both of thermally manage and optimize efficiencies in supplying the devices with adequate cooling resources.

Also disclosed herein is a delivery apparatus adjusting system that includes an adjustor having a drive pinion, and an adjustable delivery apparatus that may be implemented in the method disclosed herein. In addition, the adjustable delivery apparatus has a casing having an opening, at least one louver positioned within the opening of the casing, and an adjustor interface. The adjustor interface has a mechanical connection to the at least one louver, sliding mechanism, etc., and is configured to receive the drive pinion. The drive pinion is configured to be rotated to vary the position of the at least one louver, sliding mechanism, etc., and the flow rate of cooling resource delivery through the opening.

The delivery apparatus adjusting system disclosed herein may be a portable system that may be operated in any data center with suitable adjustable delivery apparatuses. The adjustable delivery apparatuses in this case have no motor and no embedded controller; as such, they are less expensive, less failure prone, and in some sense safer than other adjustable delivery apparatuses. Because the adjustor is removable and may be used elsewhere, the cost of the delivery apparatus adjusting system may be amortized across many data centers.

The term “cooling resource,” as used herein, refers to a fluid for use in cooling heat generating devices, such as, electronic components in a data center. As such, for instance, the cooling resources may include cool airflow, refrigerant, water, etc. In addition, the delivery of cooling resources disclosed herein may be adjusted in various manners to control the supply of cooling resources to the heat generating devices and/or heat removal devices, such as, air conditioning units. In one embodiment, the delivery of cooling resources may be adjusted through operation of delivery apparatuses having adjustable louvers or, equivalently, dampers. In another embodiment, the delivery apparatuses include fans and the delivery of cooling resources may be adjusted by varying the speeds of the fans. In a further embodiment, the delivery apparatuses include pumps and the delivery of cooling resources may adjusted by varying the operations of the pumps. In a yet further embodiment, the delivery of cooling resources may be adjusted by replacing one or more of the delivery apparatuses with other deliver apparatuses that affect the flow of cooling resources there though differently.

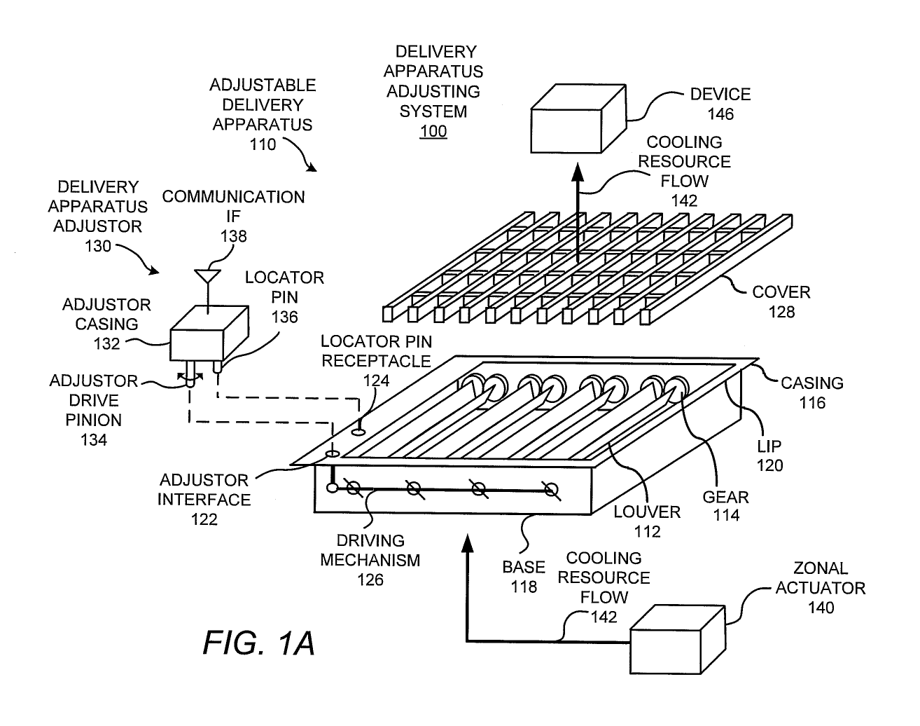

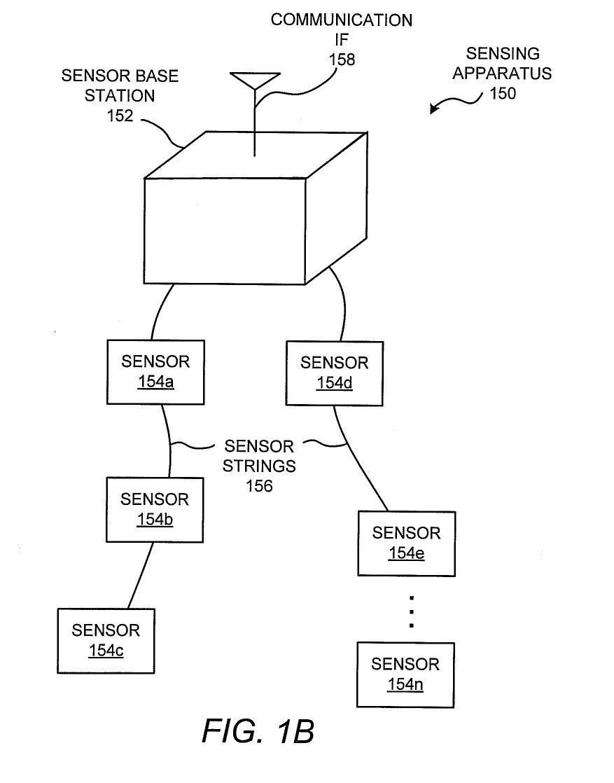

With reference first to FIG. 1A, there is shown a perspective view of a delivery apparatus adjusting system 100, according to an embodiment. It should be understood that the following description of the delivery apparatus adjusting system 100 is but one manner of a variety of different manners in which such a delivery apparatus adjusting system 100 may be configured. In addition, it should be understood that the delivery apparatus adjusting system 100 may include additional components and that some of the components described herein may be removed and/or modified without departing from a scope of the delivery apparatus adjusting system 100. It should also be clearly understood that the delivery apparatus adjusting system 100 depicted in FIG. 1 is but one example of a delivery apparatus that may be employed in the methods disclosed herein below. As such, the methods disclosed herein below may be implemented through use of various other types of delivery apparatuses, such as, delivery apparatuses having louvers fixed at various different angles, sliding mechanisms that vary the openings in the delivery apparatuses, fans, pumps, etc.

As depicted in FIG. 1A, the delivery apparatus adjusting system 100 includes an adjustable delivery apparatus 110 and a delivery apparatus adjustor 130. According to an embodiment, the adjustable delivery apparatus 110 comprises a vent tile sized to replace conventional floor tiles or vented floor tiles often employed in raised floors of data centers. According to another embodiment, the adjustable delivery apparatus 110 is sized for various other applications, such as, on a ceiling, wall, or other location with respect to a duct. In any regard, the adjustable delivery apparatus 110 is configured to receive cooling resources 142 from one or more zonal actuators 140. In addition, the cooling resources 142 from the zonal actuator(s) 140 are configured to flow through the adjustable delivery apparatus 110 to one or more devices 146 positioned to be cooled by the cooling resources 142. A zonal actuator 140 and a device 146 have been schematically illustrated in FIG. 1A.

In any regard, the adjustable delivery apparatus 110 is comprised of a casing 116, louvers 112 attached to respective gears 114, an adjustor interface 122, a locator pin receptacle 124, a driving mechanism 126, and a cover 128. The louvers 112 are positioned within an opening of the casing 116, which includes a base 118 and a lip 120. The base 118 generally provides strength and rigidity to the adjustable delivery apparatus 110 and the lip 120 substantially maintains the adjustable delivery apparatus 110 in position with respect, for instance, to an opening in a raised floor over a pressurized plenum.

The cover 124 is depicted as being formed of a grated structure having a plurality of openings through which cooling resources may readily pass. The cover 128 generally protects the louvers 112 and other components contained in the adjustable delivery apparatus 110 as personnel walk over, or equipment is moved over, the adjustable delivery apparatus 110. In addition, although the cover 124 has been depicted as forming a separate component from the casing 116 of the adjustable delivery apparatus 110, it should be understood that the cover 124 may be integrated with the casing 116 without departing from a scope of the adjustable delivery apparatus 110.

The louvers 112 are movably connected to the base 118 by motion received through a mechanical connection with the gears 114. In this regard, the rotation of the gears 114 controllably varies a position of the louvers 112. The gears 114, although not explicitly shown, may include teeth or cogs configured to mesh with neighboring gears 114. As shown in FIG. 1A, the gears 114 are connected to the driving mechanism 126, which is connected to the adjustor interface 122. The driving mechanism 126 may be composed of one or more components configured to enable rotation of the driving mechanism 126 at the adjustor interface 122 to be translated into rotation of the gears 114.

The delivery apparatus 130 is comprised of an adjustor casing 132, a adjustor drive pinion 134, a locator pin 136, and a communications interface 138. In operation, the adjustable delivery apparatus 110 is configured to receive the drive pinion 134 at the adjustor interface 122 and the locator pin 136 at the locator receptacle 124. The adjustor drive pinion 134 is configured to rotate the driving mechanism 126 to cause the position of the louvers 112 to vary and thus vary the flow rate of cooling resources through the adjustable delivery apparatus 110. In addition, the locator pin 135 and locator pin receptacle is configured to hold the adjustor casing 132 in place while the adjustor drive pinion 134 is rotated. The rotation of the adjustor interface 122 is translated into rotation of the gears 114 by the driving mechanism 126, which causes the opening in the delivery apparatus 110 to be varied.

According to an embodiment, the delivery apparatus adjustor 130 comprises a one-way or a two-way motor (not shown) that is mechanically connected to the adjustor drive pinion 134. Although not shown, the delivery apparatus adjustor 130 may include a controller or processor and other components configured to enable information received through the communication interface 138 to be processed and converted into control signals for the motor of the adjustor drive pinion 134. Alternatively, the delivery apparatus adjustor 130 may be equipped with one or more control devices through which a user may control operations of the adjustor drive pinion. In any regard, the delivery apparatus adjustor 130 may be equipped to receive electrical power through at least one electrical connection to an AC source. Moreover, or alternatively, the delivery apparatus adjustor 130 may be equipped with a battery compartment for receipt of DC power from one or more batteries.

In embodiments in which the delivery apparatus adjustor 130 receives information through the communication interface 138, the delivery apparatus adjustor 130 may receive the information from a computing device (not shown) or from one or more sensors (not shown). In one example, the delivery apparatus adjustor 130 receives control instructions from a computing device configured to track one or more conditions and determine how the flow of cooling resources through the delivery apparatus 110 is to be varied in response to the tracked conditions. In another example, the delivery apparatus adjustor 130 receives conditions detected by one or more sensors and a controller or processor of the delivery apparatus adjustor 130 determines how the cooling resource flow through the delivery apparatus 110 is to be varied based upon the received conditions. In this example, the one or more sensors may be positioned at various locations with respect to the delivery apparatus 110, such as, at an inlet or outlet of the delivery apparatus 110, at an inlet, outlet or interior location of a rack or server, etc.

The one or more sensors may comprise various types of sensors configured to detect one or more conditions, such as, temperature, pressure, mass flow rate, etc. In addition, the one or more sensors may comprise sensors used to calibrate the position of the louvers 112 with respect to the mass flow rate of cooling resources supplied through the delivery apparatus 110. By way of example, these sensors may include a flow hood sensor (not shown) positioned to detect the mass flow rate of cooling resources, such as air, flowing through the delivery apparatus 110 at various louver 112 settings.

According to another example, the one or more sensors may form part of a portable sensing apparatus 150, which is shown in FIG. 1B. As shown therein, the portable sensing apparatus 150 includes a sensor station 152 and a plurality of sensors 154a-154n arranged on sensor strings 156. The plurality of sensors 154a-154n may be positioned to detect one or more environmental conditions at various desired locations, such as, within a rack, within a row of racks, etc., and to communicate the detected conditions to the sensor base station 152. For instance, the sensors 154a-154n may be positioned along surfaces of a plurality of heat generating components (not shown), such as servers in one or more racks. Alternatively, the sensors 154a-154n may be attached to a robotic device programmed to traverse the data center and collect environmental condition data. As a further alternative, the sensors 154a-154n may be positioned on a movable cart that may be manually transported to collect data throughout the data center.

In any regard, the sensor base station 152 is equipped with a communication interface 158 through which the data collected from the sensors 154a-154n may be communicated. In one example, the sensor base station 152 is configured to communicate the collected data to the delivery apparatus adjustor 130 or a controller of the delivery apparatus adjustor 130 to enable automated control of the flow of cooling resources supplied through the delivery apparatus 110. In another example, the sensor base station 152 is configured to communicate the collected data to a computing device, such as, a laptop computer, a portable digital assistant, a server, a desktop computer, etc., which may be used to assess the detected conditions.

Thus, for instance, a user may receive the collected data and/or instructions on how the flow rate of cooling resources through the delivery apparatus 110 is to be adjusted from a computing device. In this example, and according to another embodiment, the user may manually rotate the adjustor drive pinion 134 and/or the adjustor casing 132 to cause the positions of the louvers 112 to be varied. In this embodiment, the locator pin 136 and the locator pin receptacle 124 may be omitted. Alternatively, the user may directly rotate the louvers 112, sliding mechanisms, etc., to vary the flow rate of cooling resources through the delivery apparatus 110.

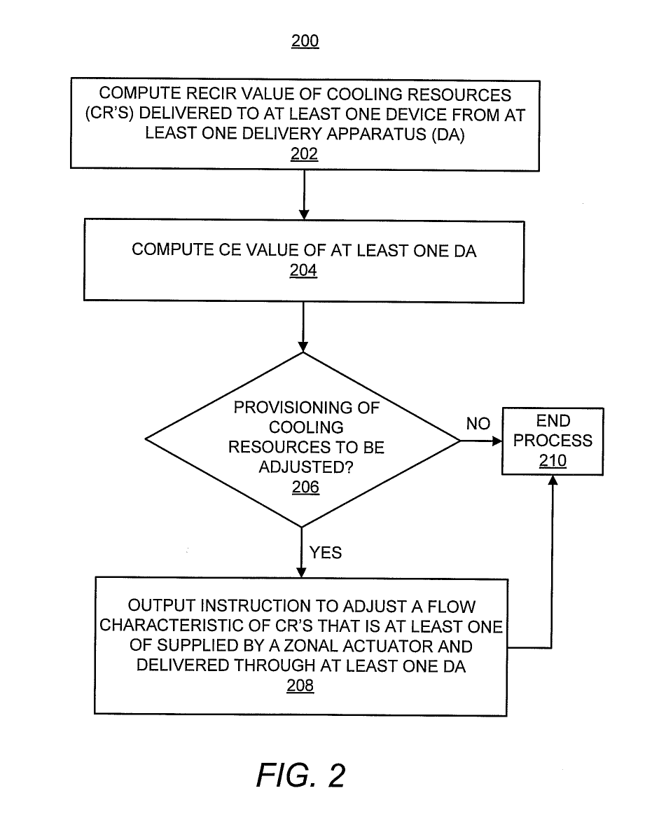

Various manners in which the delivery apparatus 110 is to be adjusted, either automatically or manually as discussed above, based upon various conditions around the delivery apparatus 110 are discussed in greater detail herein below with respect to the methods 200-400 depicted in FIGS. 2-4. FIGS. 2-4, more particularly, depict respective flow diagrams of methods of provisioning cooling resources to devices through at least one delivery apparatus 110, according to embodiments of the invention. It should be understood that the methods 200-400 may include additional steps and that some of the steps described herein may be removed and/or modified without departing from a scope of the methods 200-400.

In the descriptions of the methods 200-400, various references to the delivery apparatus adjusting system 100 disclosed in FIGS. 1A and 1B are made. It should, however, be understood that the methods 200-400 may be implemented with other systems and delivery apparatuses as specifically discussed herein below. In addition, a processor of a computing device (not shown) may perform one or more of the methods 200-400. The processor may comprise a microprocessor, a microcontroller, an ASIC, or the like and the computing device may comprise a server in a data center, a personal computer, a laptop computer, a handheld computing device, etc. Thus, for instance, the processor may perform one or more of the methods 200-400 in the control of the cooling resources supplied through one or more delivery apparatuses.

The methods 200 to 400 may be determined using components of a local workload placement index (LWPI) disclosed in U.S. Pat. No. 7,676,280, entitled “Dynamic Environmental Management”, which names Bash, Cullen E, et al. as inventors and the disclosure of which is incorporated by reference in its entirety. These components include a thermal management margin (TMM), AC margin (ACM), thermal correlation index (TCI), and hot cooling resource recirculation (HAR), which are described in the above-identified patent. The TMM is a difference between the desired inlet temperature at a device 146, such as, a piece of IT equipment, and the actual inlet temperature at the device 146. The ACM is the difference between the supply cooling resource temperature (Tsat) of a zonal actuator and a minimum Tsat that the zonal actuator can achieve, over all of the zonal actuators weighted by TCIs. HAR is the difference between the inlet temperature and the Tsat.

Turning first to FIG. 2, at step 202, a recirculation value of cooling resources (CR's) supplied to at least one device 146 from at least one delivery apparatus is computed. The at least one delivery apparatus may comprise, for instance, a vent tile having movable louvers, a vent tile having fixed louvers, or other cooling resource supply affecting apparatus. The recirculation value may comprise a difference between an inlet temperature of the at least one device 146 and an outlet temperature of the delivery apparatus. Thus, for instance, the recirculation value (RECIR) may be defined as a difference between an actual inlet temperature at a particular piece of equipment and a temperature of the cooling resources leaving the delivery apparatus (Tvent) in closest proximity to the at least one device 146. For instance, Tvent may be determined by direct measurement through use of sensors positioned at the delivery apparatus exhaust and at the inlet of the at least one device 146, by estimation based on a lowest temperature detected by sensors placed on a rack, received as an user input, estimated as a function of Tsat over all zonal actuators 140 weighted by the TCI, etc.

By way of particular example, the recirculation value (Trecirc) at a particular location may be determined using:

Trecirc(sensor)=T(sensor)−min(T(s)), Equation (1):

for each sensor s on a same rack as a sensor used to determine the inlet temperature of the at least one device 146.

Alternately, the recirculation value may be determined using

Trecirc(sensor)=max(T(s))−min(T(s)), Equation (2):

in which max(T(s)) is a maximum temperature for each sensor s on the same rack as the sensor used to determine the inlet temperature of the at least one device 146, and min(T(s)) is a minimum temperature for each sensor s on the same rack as the sensor used to determine the inlet temperature of the at least one device 146. In addition, Trecirc(sensor) may be defined as the HAR for the sensor.

At step 204, a cooling effectiveness (CE) value of the at least one delivery apparatus is computed. The CE value comprises a measure of the effectiveness of the at least one delivery apparatus in supplying cooling resources to the at least one device 146. The CE value of a particular delivery apparatus (DCE) may be defined as:

DCE=TMM−RECIR. Equation (3)

At step 206, a determination as to whether provisioning of cooling resources supplied to at least one device 146 through the at least one delivery apparatus is to be adjusted based upon computed recirculation and CE values is made. Examples of when the provisioning of cooling resources are to be adjusted are discussed in greater detail herein below.

In response to a determination that the provisioning of cooling resources supplied to the at least one device 146 is to be adjusted, an instruction to adjust at least one of a flow characteristic such as, temperature, flow rate, etc., of cooling resources supplied by the at least one zonal actuator 140 and delivered through the at least one delivery apparatus is outputted as indicted at step 208. The at least one zonal actuator 140 may comprise an AC unit that is in the closest proximity to the at least one delivery apparatus and/or the AC unit that has previously been identified as affecting the temperature of cooling resources supplied through the at least one delivery apparatus to at least a predetermined extent. In one example, the processor (not shown) performing the method 200 may output information to be displayed on a monitor of a computing device to indicate to a user that the flow characteristic of the cooling resources that is at least one of supplied by the at least one zonal actuator 140 and delivered through the at least one delivery apparatus is to be adjusted. In this example, a user may manually adjust the flow characteristics of the cooling resources delivered to the device 146 by, for instance, replacing the delivery apparatus with another delivery apparatus having a different affect on the delivery of the cooling resources, by manually adjusting the position of louvers in an adjustable delivery apparatus, by manually adjusting a zonal actuator 140 setting, etc. In another example, the processor may output control signals to the at least one zonal actuator 140 or a controller of the delivery apparatus 110 at step 208 to automatically control adjustments to either or both of a delivery apparatus and a zonal actuator. As discussed above, the opening in the delivery apparatus 110 may be varied through operation of the delivery apparatus adjustor 130.

In any regard, if a determination that the provisioning of cooling resources is not to be adjusted at step 206 is made and/or following step 208, the method 200 may end, as indicated at step 210. The method 200 may also be repeated for another delivery apparatus or as otherwise desired.

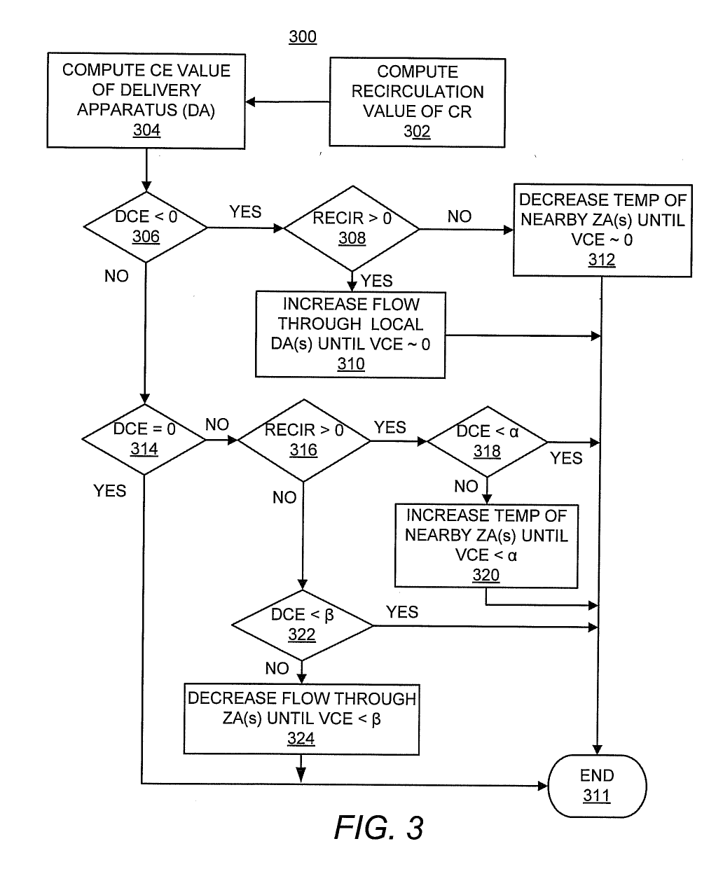

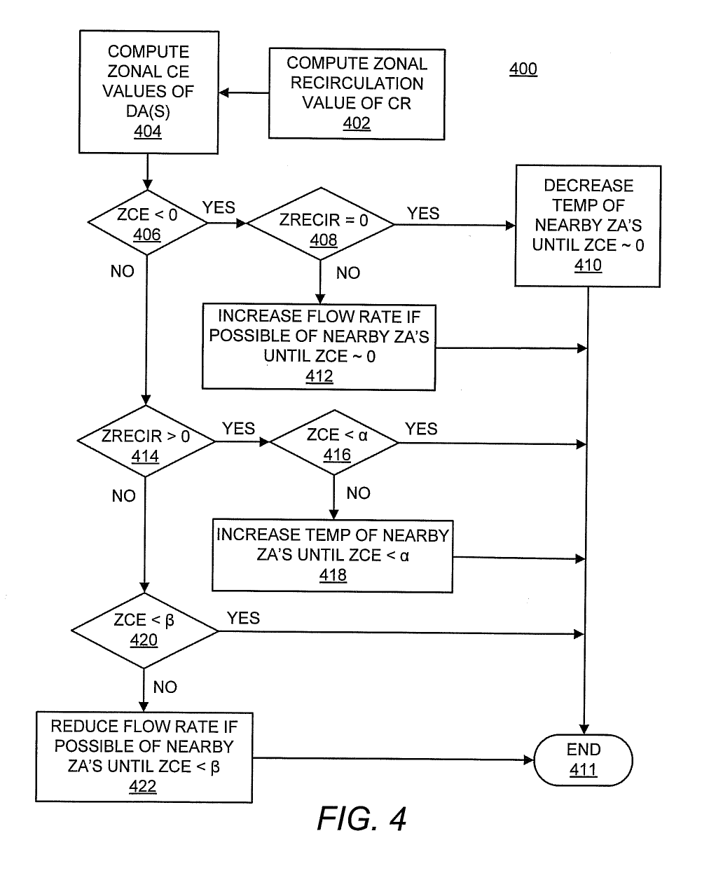

Various manners in which decisions pertaining to whether the provisioning of cooling resource are to be adjusted at step 206 are discussed in greater detail herein below with respect to FIGS. 3 and 4.

With reference first to FIG. 3, the method 300 may be initiated with the performance of steps 302 and 304, which are equivalent to steps 202 and 204 described above with reference to the method 200 in FIG. 2. In addition, steps 302 and 304 may be performed for one or more delivery apparatuses (DA's), such as, vent tiles, or other cooling resource characteristic modifying devices, and devices 146 in an infrastructure, such as, servers and/or racks in a data center.

At step 306, a determination as to whether the CE value for at least one of the delivery apparatuses (DCEs) is a negative value is made. In response to a determination that the DCE value for the at least one delivery apparatus is a negative value at step 306, a determination as to whether the recirculation value for at least device 146 that receives cooling resource flow from the at least one delivery apparatus is a positive value is made, as indicated at step 308.

At step 310, in response to the recirculation value for the at least one device 146 being a positive value at step 308, an instruction that the flow rate of cooling resources supplied through the at least one delivery apparatus is to be increased until the DCE is approximately equal to zero is outputted, as discussed above with respect to step 208 in FIG. 2. Thus, for instance, the processor may output a control signal to an actuator of the at least one delivery apparatus to automatically adjust the opening of the at least one delivery apparatus. For instance, in a data center 200 using adjustable delivery apparatuses as discussed with regard to FIG. 1A hereinabove, the processor may communicate a control signal to the delivery apparatus adjustor 130 to vary the positions of the louvers 112 in the delivery apparatus opening up the delivery apparatus. In addition, or alternatively, the processor may output instructions that a user may follow by increasing the opening of the at least one delivery apparatus 110 to thereby increase the mass flow rate of cooling resource flow supplied through the at least one delivery apparatus 110 to the at least one device 146. Alternatively, the user may increase the flow rate of cooling resources supplied through the delivery apparatus by replacing the delivery apparatus with a delivery apparatus that allows for greater flow of cooling resources therethrough.

However, in response to the recirculation value for the at least one device 146 being determined to be a negative value at step 308, an instruction that a temperature of cooling resources supplied by at least one nearby zonal actuator 140, such as air conditioning units that supply cool airflow to the at least one delivery apparatus, is to be decreased until the DCE value is approximately zero is outputted as indicated at step 312. For instance, the processor may output a control signal to an actuator of the at least one zonal actuator 140 to automatically adjust the temperature of the cooling resources supplied by the at least one zonal actuator 140. In addition, or alternatively, the processor may output instructions that a user may follow by decreasing the temperature of cooling resources supplied by the at least one zonal actuator 140.

Following ether of steps 310 or 312, the method 300 may end as indicated at step 311.

With reference back to step 306, in response to a determination that the DCE value is not a negative value, a determination as to whether the DCE value is equal to zero is made at step 314. In response to the DCE value being equal to zero, the method 300 may end as indicated at step 311. Alternatively, in response to a determination that the DCE value is not equal to zero, a determination as to whether the recirculation value is a positive value is made, as indicated at step 316.

In response to a determination that the recirculation value is a positive value, a determination as to whether the DCE value falls below a first predetermined value (α) is made as indicated at step 318. The predetermined value (α) generally comprises a value that defines how efficiently the infrastructure is to be run. Thus, for instance, the first predetermined value (α) is a relatively lower number for infrastructures that are to be run at higher levels of efficiency. By way of a particular example, the first predetermined value (α) is approximately 2° C.

However, in response to the DCE value exceeding the first predetermined value (α), an instruction that a temperature of cooling resource flow supplied by the at least one zonal actuator 140 to the at least one delivery apparatus is to be increased until the DCE value falls below the first predetermined value (α) is outputted, as indicated at step 320. Any of the manners discussed above with respect to how the processor outputs instructions may be implemented at step 320. In response to the DCE value falling below the first predetermined value (α) at step 318 or following step 320, the method 300 may end as indicated at step 311.

With reference back to step 316, in response to a determination that the recirculation value is a negative value, a determination as to whether the DCE value falls below a second predetermined value (β) is made as indicated at step 322. The second predetermined value (β) generally comprises a value that defines how efficiently the infrastructure is to be run. Thus, for instance, the second predetermined value (β) is a relatively lower number for infrastructures that are to be run at higher levels of efficiency. By way of a particular example, the second predetermined value (β) is approximately 2° C.

In response to the DCE value exceeding the predetermined value (β), an instruction that the flow of cooling resources through an opening of the at least one delivery apparatus is to be reduced until the DCE value falls below the predetermined value (β) is outputted as indicated at step 324. Any of the manners discussed above with respect to how the processor outputs instructions may be implemented at step 324. In addition, in response to the DCE value falling below the second predetermined value (β) at step 322 or following step 324, the method 300 may end as indicated at step 311.

Generally speaking, steps 306-312 may be performed to substantially ensure that the at least one device 146 receives adequate cooling resource provisioning and are thus performed for thermal management of the at least one device 146. In addition, steps 314-324 may be performed to improve the efficiency of the at least one zonal actuator 140 in providing adequate cooling resource provisioning to the at least one device 146.

Turning now to FIG. 4, the method 400 differs from the method 300 depicted in FIG. 3 in that the method 400 is applicable to zones of delivery apparatuses, devices 146, and zonal actuators 140. The zones discussed herein may comprise, for instance, a grouping of delivery apparatuses, devices 146, and zonal actuators 140 that are in a common area within an infrastructure, such as, servers in one or more racks, a row of racks, a section of a data center, etc. In addition, the zonal actuators 140 are equipped with components for varying the temperatures and the mass flow rates of cooling resources supplied to the delivery apparatuses.

At step 402, a zonal recirculation value of the cooling resources supplied to a plurality of devices 146 from a plurality of delivery apparatuses in one or more zones is computed. By way of example, the zonal recirculation (ZRECIRC) value of a particular zone is computed by:

ZRECIRC(zone)=mean ([Tinₘₐₓ(r)−Tinₘᵢₙ(r)]) for the racks (r) in the zone. Equation (4)

As shown by Equation (4), the zonal recirculation (Zrecirc) value of a particular zone may be equal to the mean value of the difference between the maximum temperature measurement and a minimum temperature measurement at each rack contained in the zone.

In addition, a thermal management margin of a zone (ZTMM) may be calculated as follows:

ZTMM=mean([Tref(s)−Tin(s)]) for the sensors (s) in the zone. Equation (5)

As shown by Equation (5), the zonal thermal management margin (ZTMM) may be equal to the mean value of the differences between the reference temperatures and the temperatures detected at the inlets of the racks, for instance, temperatures detected at the outlets of the delivery apparatuses 110 in a particular zone.

At step 404, a zonal cooling effectiveness (ZCE) value of the delivery apparatuses in one or more zones is computed. By way of example, the ZCE for a particular zone is computed by:

ZCE=ZTMM−Zrecirc. Equation (6)

Alternatively, however, the ZCE value may be determined through various other measurements. For instance, the ZCE value may be determined based upon the hot cooling resource recirculation (HAR) in the zone.

At step 406, a determination as to whether the ZCE value is a negative value is made. In response to a determination that the ZCE value is a negative value at step 406, a determination as to whether the zonal recirculation (ZRECIR) value is equal to zero is made at step 408. In response to the zonal recirculation value being equal to zero, an instruction that temperatures of cooling resources supplied by the nearby zonal actuators 140 are to be decreased until the ZCE value is approximately zero is outputted, as indicated at step 410. Any of the manners discussed above with respect to how the processor outputs instructions may be implemented at step 410.

With reference back to step 408, in response to the zonal recirculation value being a positive value, an instruction that the flow rates of cooling resources supplied by the nearby zonal actuators 146 are to be increased, if possible, until the ZCE value is approximately zero is outputted, as indicated at step 412. The flow rates of the cooling resources may be increased by, for instance, increasing the speeds at which fans of the zonal actuators 146 are operated until maximum speed levels of the fans are reached. In another example, the flow rates of the cooling resources may be increased by, for instance, increasing the flow rate of the cooling resources through increased pressure applied by one or more pumps of the zonal actuators 146. Any of the manners discussed above with respect to how the processor outputs instructions may be implemented at step 412. In addition, following either of the steps 410 and 412 the method 400 may end as indicated at step 411.

With reference back to step 406, in response to a determination that the ZCE value is a positive value, a determination as to whether the zonal recirculation value is a positive value is made, as indicated at step 414. In response to the zonal recirculation value being a positive value, a determination as to whether the ZCE falls below a first predetermined value (α) is made. The first predetermined value (α) generally comprises a value that defines how efficiently the infrastructure is to be run. Thus, for instance, the first predetermined value (α) is a relatively lower number for infrastructures that are to be run at higher levels of efficiency. By way of a particular example, the first predetermined value (α) is approximately 2° C.

In response to the ZCE exceeding the first predetermined value (α), an instruction that temperatures of the cooling resources supplied by nearby zonal actuators 146 are to be increased until the zonal CE falls below the first predetermined value (α) is outputted as indicated at step 418. Any of the manners discussed above with respect to how the processor outputs instructions may be implemented at step 418. In response to the ZCE value falling below the first predetermined value (α) at step 416 or following step 418, the method 400 may end as indicated at step 411.

With reference back to step 414, in response to the zonal recirculation value being determined to be a negative value, a determination as to whether the ZCE falls below a second predetermined value (β) is made as indicated at step 422. The second predetermined value (β) generally comprises a value that defines how efficiently the infrastructure is to be run. Thus, for instance, the second predetermined value (β) is a relatively lower number for infrastructures that are to be run at higher levels of efficiency. By way of a particular example, the second predetermined value (β) is approximately 2° C.

In response to the ZCE value exceeding the second predetermined value (β), an instruction that the flow rate at which cooling resources are supplied by the nearby zonal actuators 140 are to be decreased, if possible, until the zonal CE falls below the second predetermined value (β) is outputted. The flow rates of the cooling resources may be decreased by, for instance, decreasing the speeds at which fans of the zonal actuators 146 are operated until minimum speed levels of the fans are reached. The minimum speed levels of the fans may comprise, for instance, the speeds that supply a predetermined minimum level of pressurized cooling resources to the devices 146. In another example, the flow rates of the cooling resources may be decreased by, for instance, decreasing the flow rate of the cooling resources through decreased pressure applied by one or more pumps of the zonal actuators 146. Any of the manners discussed above with respect to how the processor outputs instructions may be implemented at step 420. In addition, in response to the ZCE value falling below the second predetermined value (β) at step 420 or following step 422, the method 400 may end as indicated at step 411.

According to an embodiment the method 400 is implemented for each of a plurality of zones in an infrastructure, such as, a data center. As such, some zonal actuators 140 may be operated to increase temperatures of the cooling resources supplied by the zonal actuators 140 while other zonal actuators 140 may be operated to decrease temperatures of cooling resources supplied by the zonal actuators 140.

Generally speaking, steps 406-412 may be performed to substantially ensure that the devices 146 in one or more zones receive adequate cooling resource provisioning and are thus performed for thermal management of the devices 146. In addition, steps 414-422 may be performed to improve the efficiencies of the zonal actuators 140 in providing adequate cooling resource provisioning to the devices 146.

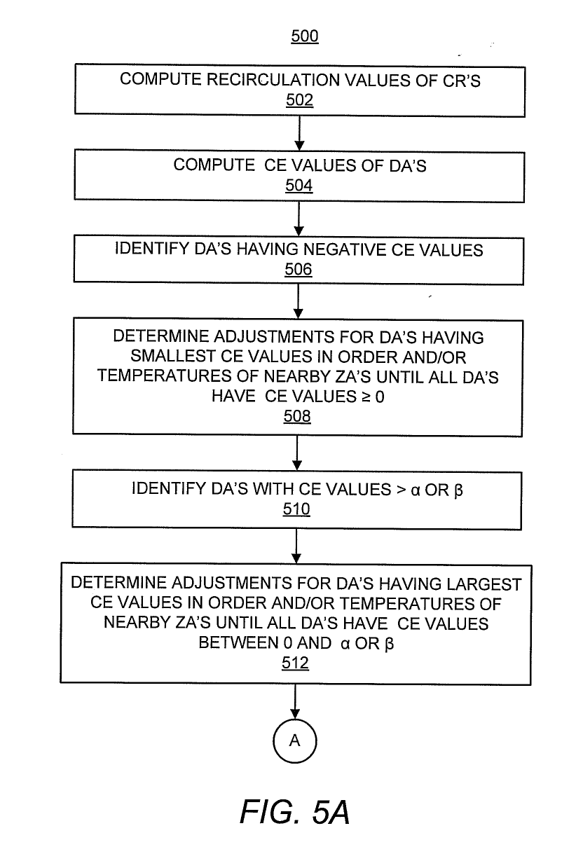

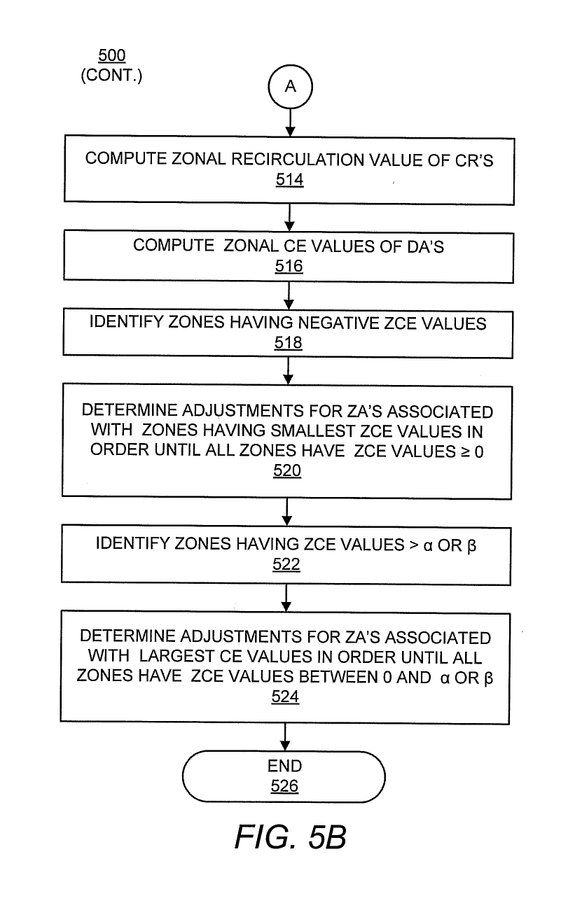

According to an embodiment, either or both of the methods 300 and 400 may be implemented as part of a larger scale cooling resource provisioning operation that identifies, for instance, the order in which the delivery apparatuses and/or zonal actuators 140 are to be adjusted to meet thermal and/or efficiency objectives. An example of this embodiment is depicted in FIGS. 5A and 5B, which collectively depict a flow diagram 500 of a method of provisioning cooling resources to a plurality of locations in an infrastructure through a plurality of delivery apparatuses.

As shown therein, steps 502 and 504, which are equivalent to steps 202 and 204 described above with reference to the method 200 in FIG. 2, are performed for a plurality of delivery apparatuses in an infrastructure. For instance, steps 502 and 504 may be performed for all of the delivery apparatuses 110 in an infrastructure, such as, a data center, using data collected from a plurality of sensors.

At step 506, the delivery apparatuses having negative CE values are identified. In addition, at step 508, adjustments for the delivery apparatuses having the smallest CE values and/or the temperatures of nearby zonal actuators 140 are determined in order until all the delivery apparatuses have CE values that are greater than or equal to zero. Thus, the delivery apparatuses having the smallest CE values or the zonal actuators 140 that are nearby to the delivery apparatuses having the smallest CE values are determined to be adjusted prior to the delivery apparatuses having relatively larger CE values or the zonal actuators 140 that are nearby to the delivery apparatuses having relatively larger CE values. More particularly, for instance, the flow rates of cooling resources delivered through the delivery apparatuses having negative CE values may be increased as discussed above with respect to step 310 in FIG. 3 and/or the temperatures of the cooling resources supplied by the nearby zonal actuators 140 may be decreased as indicated at step 312 in FIG. 3.

At step 510, the delivery apparatuses having CE values that exceed either a first or a second predetermined value (α) or (β) are identified, which have been described herein above with respect to FIG. 3. In addition, at step 512, adjustments for the delivery apparatuses having the largest CE values that exceed either the first or the second predetermined value (α) or (β) and/or the zonal actuators 140 nearby to those delivery apparatuses are determined to be effectuated in order until all of the delivery apparatuses have CE values between zero and the first or the second predetermined value (α) or (β). Thus, for instance, the temperatures of the cooling resources supplied to the delivery apparatuses having CE values that exceed the first predetermined value (α) may be increased as indicated at step 320 in FIG. 3. As another example, the flow rates of the cooling resources supplied through the delivery apparatuses having CE values that exceed the second predetermined value (β) may be reduced as indicated at step 324 in FIG. 3.

In instances in which manipulations of the delivery apparatuses fail to result in the CE values reaching the condition of being between zero and the first or the second predetermined value (α) or (β), the method 500 may end following step 512. However, if these conditions are reached, then at step 514, the zonal recirculation values of cooling resource flow in a plurality of zones are computed, for instance, as discussed above with respect to step 402 in FIG. 4. In addition, at step 516, the zonal CE values of the delivery apparatuses for each of the plurality of zones are computed as discussed above with respect to step 404 in FIG. 4.

At step 518, the zones having negative ZCE values are identified. In addition, at step 520, adjustments for the zonal actuators 140 associated with the zones having the smallest ZCE values are determined to be effectuated in order until all of the zones having ZCE values that are greater than or equal to zero are determined. Thus, for instance, at step 520, the temperatures of the cooling resources supplied by the zonal actuators 140 associated with those zones may be decreased as indicated at step 410 in FIG. 4. In addition, or alternatively, the flow rates of cooling resources supplied by the zonal actuators 140 associated with those zones may be increased as indicated at step 412 in FIG. 4.

At step 522, zones having ZCE values that exceed either a first or a second predetermined value (α) or (β) are identified. In addition, at step 524, adjustments for the zonal actuators 140 associated with those zones are determined to be effectuated in order until all of the zones have ZCE values between zero and the first or the second predetermined value (α) or (β). Thus, for instance, the temperatures of cooling resources supplied by the zonal actuators 140 associated with those zones may be increased as indicated at step 418 in FIG. 4. In addition, or alternatively, the flow rates of cooling resources supplied by the zonal actuators 140 associated with those zones may be decreased as indicated at step 422 in FIG. 4.

At step 526, the method 500 may end.

Some or all of the operations set forth in the methods 300-500 may be contained as one or more utilities, programs, or subprograms, in any desired computer accessible or readable medium. In addition, the methods 300-500 may be embodied by a computer program, which may exist in a variety of forms both active and inactive. For example, they may exist as software program(s) comprised of program instructions in source code, object code, executable code or other formats. Any of the above may be embodied on one or more computer readable storage devices or media.

Exemplary computer readable storage devices include conventional computer system RAM, ROM, EPROM, EEPROM, and magnetic or optical disks or tapes. Concrete examples of the foregoing include distribution of the programs on a CD ROM or via Internet download. It is therefore to be understood that any electronic device capable of executing the above-described functions may perform those functions enumerated above.

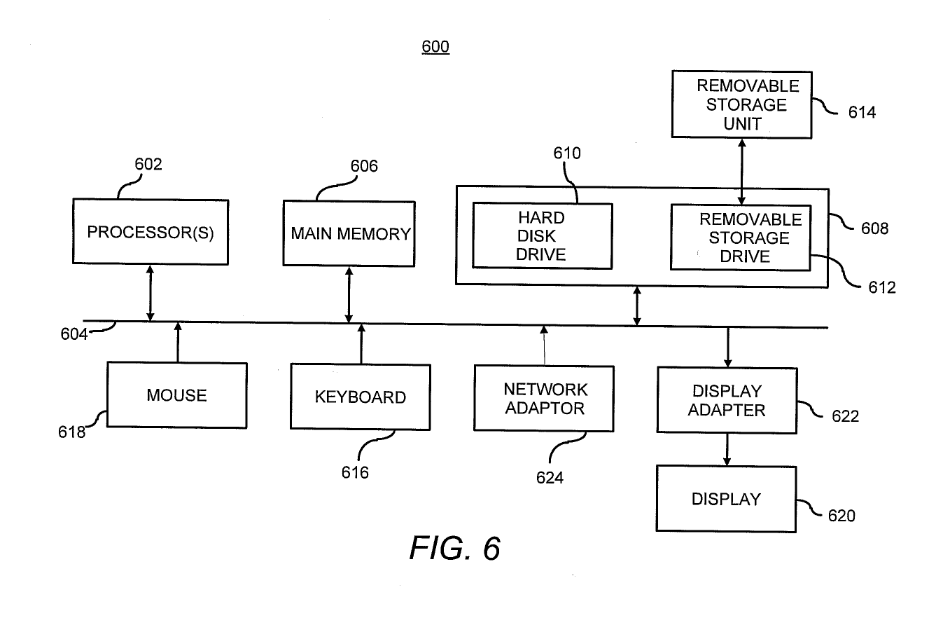

FIG. 6 illustrates a computer system 600, which may be employed to perform the various functions of the computing device described herein above, according to an example. In this respect, the computer system 600 may be used as a platform for executing or implementing one or more of the methods 200-500.

The computer system 600 includes a processor 602, which may be used to execute some or all of the steps described in the methods 200-500. Commands and data from the processor 602 are communicated over a communication bus 604. The computer system 600 also includes a main memory 606, such as a random access memory (RAM), where the program code may be executed during runtime, and a secondary memory 608. The secondary memory 608 includes, for example, one or more hard disk drives 610 and/or a removable storage drive 612, representing a floppy diskette drive, a magnetic tape drive, a compact disk drive, etc., where a copy of the program code for managing fluid flow distribution in an environment may be stored.

The removable storage drive 610 reads from and/or writes to a removable storage unit 614 in a well-known manner. User input and output devices may include a keyboard 616, a mouse 618, and a display 620. A display adaptor 622 may interface with the communication bus 604 and the display 620 and may receive display data from the processor 602 and convert the display data into display commands for the display 620. In addition, the processor 602 may communicate over a network, for instance, the Internet, LAN, etc., through a network adaptor 624.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

What is claimed is:

1. A method for provisioning cooling resources to at least one device through at least one delivery apparatus, wherein the at least one delivery apparatus is supplied with cooling resources by at least one zonal actuator, said method comprising:
computing a recirculation value of cooling resources supplied to the at least one device from the at least one delivery apparatus, wherein the recirculation value comprises a difference between an inlet temperature of the at least one device and an outlet temperature of the at least one delivery apparatus;
computing a cooling effectiveness (CE) value of the at least one delivery apparatus, wherein the CE value comprises a measure of the effectiveness of the at least one delivery apparatus in delivering cooling resources to the at least one device;
determining whether provisioning of the cooling resources delivered to the at least one device through the at least one delivery apparatus is to be adjusted based upon the computed recirculation and CE values; and
outputting an instruction to adjust a flow characteristic of cooling resources that is at least one of supplied by the at least one zonal actuator and delivered through the at least one delivery apparatus in response to a determination that provisioning of the cooling resource is to be adjusted.

2. The method according to claim 1, wherein outputting the instruction further comprises outputting one of a control signal to the at least one zonal actuator to automatically adjust the flow characteristic of cooling resources supplied by the at least one zonal actuator and a control signal to an actuator of the at least one delivery apparatus to automatically adjust the flow characteristic of cooling resources delivered through the at least one delivery apparatus.

3. The method according to claim 1, wherein determining whether provisioning of the cooling resources delivered to the at least one device through the at least one delivery apparatus is to be modified further comprises:
determining whether the CE value is a negative value;
determining whether the recirculation value is a positive value in response to the CE value being a negative value;
in response to the recirculation value being a positive value, outputting an instruction that a flow rate of cooling resources delivered through the at least one delivery apparatus is to be increased; and
in response to the recirculation value being a negative value, outputting an instruction that a temperature of cooling resources supplied by the at least one zonal actuator to the at least one delivery apparatus is to be decreased until the CE value is approximately zero.

4. The method according to claim 1, wherein determining whether provisioning of the cooling resources supplied to the at least one device through the at least one delivery apparatus is to be modified further comprises:
determining whether the CE value is a negative value;
determining whether the CE value is equal to zero in response to a determination that the CE value is not a negative value; and
in response to a determination that the CE value is not equal to zero, determining whether the recirculation value is a positive value.

5. The method according to claim 4, further comprising:
in response to a determination that the recirculation value is a positive value, determining whether the CE value falls below a predetermined value;
in response to the CE value exceeding the predetermined value, outputting an instruction that a temperature of the cooling resources supplied by the at least one zonal actuator to the at least one delivery apparatus is to be increased until the CE value falls below the predetermined value.

6. The method according to claim 4, further comprising:
in response to a determination that the recirculation value is a negative value, determining whether the CE value falls below a predetermined value; and
in response to the CE value exceeding the predetermined value, outputting an instruction that delivery of cooling resources through the at least one delivery apparatus is to be reduced until the CE value falls below the predetermined value.

7. The method according to claim 1, further comprising:
computing recirculation values of cooling resources supplied to a plurality of devices from a plurality of delivery apparatuses;
is computing CE values of the plurality of delivery apparatuses;
identifying one or more of the plurality of delivery apparatuses having negative CE values; and
outputting an instruction to adjust at least one of a temperature of cooling resources supplied by one or more zonal actuators and a flow rate of cooling resources delivered through the plurality of delivery apparatuses in areas of the identified one or more of the plurality of delivery apparatuses having negative CE values in order starting with the delivery apparatuses and the zonal actuators in areas of delivery apparatuses having the lowest CE values.

8. The method according to claim 7, further comprising:
identifying one or more of the plurality of delivery apparatuses having positive CE values that exceed a predetermined value; and
outputting an instruction to adjust at least one of a temperature of cooling resources supplied by one or more of the zonal apparatuses and flow rates of cooling resources delivered through the plurality of delivery apparatuses in areas of the identified one or more of the plurality of delivery apparatuses having positive CE values in order starting with the delivery apparatuses and zonal actuators in areas of delivery apparatuses having the highest CE values that exceed the predetermined value.

9. The method according to claim 1, wherein a plurality of the devices, a plurality of the delivery apparatuses, and a plurality of the zonal actuators form part of a zone in an infrastructure, said method further comprising:
computing a zonal recirculation value of the cooling resources supplied to the plurality of devices from the plurality of delivery apparatuses;
computing a zonal CE value of the plurality of delivery apparatuses;
determining whether the zonal CE value is a negative value;
determining whether the zonal recirculation value is equal to zero in response to the zonal CE value being a negative value;
in response to the zonal recirculation value being equal to zero, outputting an instruction that temperatures of cooling resources supplied by nearby zonal actuators are to be decreased until the zonal CE value is approximately zero; and
in response to the zonal recirculation value being a positive value, outputting an instruction that speeds of fans in the nearby zonal actuators are to be increased until the CE value is approximately zero.

10. The method according to claim 9, further comprising:
in response to the zonal CE being a positive value, determining whether the zonal recirculation value is a positive value;
in response to the zonal recirculation value being a positive value, determining whether the zonal CE falls below a first predetermined value;
in response to the zonal CE exceeding the first predetermined value, outputting an instruction that temperatures of the cooling resources supplied by nearby zonal actuators are to be increased until the zonal CE falls below the first predetermined value;
in response to the zonal recirculation value being a negative value, determining whether the zonal CE falls below a second predetermined value; and
in response to the zonal CE exceeding the second predetermined value, outputting an instruction that speeds of fans in the nearby zonal actuators are to be decreased until the zonal CE falls below the second predetermined value.

11. The method according to claim 10, wherein the infrastructure comprises a plurality of zones, said method further comprising:
identifying one or more zones in the infrastructure having negative zonal CE values; and
outputting an instruction to adjust at least one of temperatures of cooling resources supplied by one or more zonal actuators, flow rates of cooling resources supplied by the one or more zonal actuators, and flow rates of cooling resources through the plurality of delivery apparatuses in the identified one or more zones in order starting with the zones having the lowest zonal CE values.

12. The method according to claim 11, further comprising:
identifying one or more of the zones having positive zonal CE values that exceed the second predetermined value; and
outputting an instruction to adjust at least one of temperatures of cooling resources supplied by one or more of the zonal actuators, flow rates of cooling resources supplied by one or more of the zonal actuators, and flow rates of cooling resources through openings of the plurality of delivery apparatuses in areas of the identified one or more zones in order starting with the zones in areas of delivery apparatuses having the highest CE values that exceed the second predetermined value.

13. The method according to claim 1, wherein the at least one delivery apparatus comprises an adjustor interface having a mechanical connection to at least one louver, said method further comprising:
inserting a drive pinion of an adjustor into the adjustor interface; and
wherein outputting an instruction to adjust an opening of the at least one delivery apparatus further comprises communicating a control signal to the adjustor to rotate the drive pinion and adjust the at least one louver position to thereby adjust the flow rate of cooling resources through the at least one delivery apparatus.

14. A system comprising:
an adjustor having a drive pinion; and
a delivery apparatus having,
a casing having an opening;
at least one louver positioned within the opening of the casing;
an adjustor interface having a mechanical connection to the at least one louver, said adjustor interface being configured to receive the drive pinion, and wherein the drive pinion is configured to be rotated to vary the position of the at least one louver and thereby the flow rate of cooling resources through the opening.

15. The system according to claim 14, wherein the adjustor further comprises:
an actuator for rotating the drive pinion; and
a communication interface for communicating with a controller, wherein the adjustor is configured to operate the actuator to rotate the drive pinion in response to communications received from the controller.

16. The system according to claim 15, further comprising:
a portable sensor apparatus having a plurality of sensors; and
a sensor station configured to receive data collected by the plurality of sensors, said sensor station being configured to communicate the collected data to at least one of the controller and the adjustor.

17. A computer readable storage medium on which is embedded one or more computer programs, said one or more computer programs implementing a method for provisioning cooling resources to at least one device through at least one delivery apparatus, said one or more computer programs comprising computer readable code for:
computing a recirculation value of cooling resources supplied to the at least one device from the at least one delivery apparatus, wherein the recirculation value comprises a difference between an inlet temperature of the at least one device and an outlet temperature of the at least one delivery apparatus;
computing a cooling effectiveness (CE) value of the at least one delivery to apparatus, wherein the CE value comprises a measure of the effectiveness of the at least one delivery apparatus in supplying cooling resources to the at least one device;
determining whether provisioning of the cooling resources supplied to the at least one device through the at least one delivery apparatus is to be adjusted is based upon the computed recirculation and CE values; and
outputting an instruction to adjust a flow characteristic of cooling resources that is one of supplied by the at least one zonal actuator and delivered through the at least one delivery apparatus in response to a determination that provisioning of the cooling resource is to be adjusted.

18. The computer readable storage medium according to claim 17, said one or more computer programs further comprising a set of instructions for:
computing recirculation values of cooling resources delivered to a plurality of devices from a plurality of delivery apparatuses;
computing CE values of the plurality of delivery apparatuses;
identifying one or more of the plurality of delivery apparatuses having negative CE values; and
outputting an instruction to adjust at least one of a temperature of cooing resources supplied by one or more zonal actuators and a flow rate of cooling resources delivered through the plurality of delivery apparatuses in areas of the identified one or more of the plurality of delivery apparatuses having negative CE values in order starting with the delivery apparatuses and the zonal actuators in areas of delivery apparatuses having the lowest CE values.

19. The computer readable storage medium according to claim 17, said one or more computer programs further comprising a set of instructions for:
identifying one or more of the plurality of delivery apparatuses having positive CE values that exceed a predetermined value; and
outputting an instruction to adjust at least one of a temperature of cooling resources supplied by one or more of the zonal apparatuses and flow rates of cooling resources delivered through the plurality of delivery apparatuses in areas of the identified one or more of the plurality of delivery apparatuses having positive CE values in order starting with the delivery apparatuses and zonal actuators in areas of delivery apparatuses having the highest CE values that exceed the predetermined value.

20. The computer readable storage medium according to claim 17, said one or more computer programs further comprising a set of instructions for:
identifying one or more zones in the infrastructure having negative zonal CE values; and
outputting an instruction to adjust at least one of temperatures of cooling resources supplied by one or more zonal actuators, flow rates of cooling resources supplied by the one or more zonal actuators, and flow rates of cooling resources through the plurality of delivery apparatuses in the identified one or more zones in order starting with the zones having the lowest zonal CE values.
